(19) United States
(12) Patent Application Publication
(10) Pub. No.: US 2011/0189617 A1
(43) Pub. Date: Aug. 4, 2011

(54) METHOD OF FORMING ORGANIC THIN FILM AND EXPOSURE METHOD

(76) Inventor: Yoshihiro NAKA, Mie (JP)

(21) Appl. No.: 13/020,109

(22) Filed: Feb. 3, 2011

(30) Foreign Application Priority Data
Feb. 4, 2010 (JP) 2010-023216

(51) Int. Cl. G03F 7/20; B05D 3/02; B05D 1/30; B05D 5/00

(52) U.S. Cl. 430/325; 427/384

(57) ABSTRACT

According to one embodiment, a method of forming an organic thin film includes coating organic solution onto a substrate and heating the coated organic solution after the coating. The organic solution contains a first component and a second component. The second component has higher hydrophobicity than hydrophobicity of the first component. The coating includes making the organic solution to be dropped onto the substrate, equalizing a thickness of the dropped organic solution in an atmosphere containing a vapor at a first vapor pressure, and equalizing the thickness of the dropped organic solution in an atmosphere containing the vapor at a second vapor pressure after the equalization in the atmosphere containing the vapor at the first vapor pressure. The vapor is formed by a vaporization of a liquid. The second vapor pressure is higher than the first vapor pressure.

### CROSS-REFERENCE TO RELATED APPLICATIONS

This application is based upon and claims the benefit of priority from the prior Japanese Patent Application No. 2010-023216, filed on Feb. 4, 2010; the entire contents of all of which are incorporated herein by reference.

### FIELD

Embodiments described herein relate generally to a method of forming an organic thin film, and an exposure method.

### BACKGROUND

In a process for manufacturing a semiconductor device, attention has been focused on an exposure method called a liquid immersion exposure. In the liquid immersion exposure, a portion between a projecting optical system (projecting lens) of an exposure apparatus and a resist film formed on a substrate, which should be exposed, is filled with immersion liquid (pure water) having high refractive index, while forming a latent image onto the resist film. Since the portion between the projecting optical system and the resist film is filled with the immersion liquid (pure water), a deeper depth of focus can be obtained.

In the liquid immersion exposure, if the pure water is present so as to be in direct contact with the resist film formed on the substrate, a photoacid generator might be eluted from the resist film (chemically-amplified resist) into the pure water. When the photoacid generator is eluted from the resist film into the pure water, the eluted photoacid generator causes a contamination to the projecting lens, which deteriorates an imaging precision (resolution) by the exposure apparatus in a later exposure process. When the photoacid generator is eluted from the resist film into the pure water, the amount of the photoacid generators contained in the resist film is decreased, so that the emission of acid (H⁺) due to the photoacid generator on the region exposed in the later exposure process is decreased, which deteriorates photosensitive precision (photosensitive performance) by the resist film. Therefore, a defect formation of a resist pattern (generation of water spot) might be caused.

On the other hand, there has been proposed a technique of preventing the invasion of the pure water into the resist film by covering the resist film with a protective coating (top coat) having hydrophobicity. There has also been proposed a technique of providing hydrophobicity to the surface of the resist film by adding a component, which has high hydrophobicity, to the resist film. The resist employing the latter technique is referred to as a top-coatless resist (hydrophobic-component-containing resist).

Japanese Patent Application Laid-Open No. 2006-309245 describes that a photoresist composition containing a photoresist resin, a photoacid generator, and an additive that is substantially immiscible with the photoresist resin is coated (spin-coated) onto a semiconductor wafer, and then, the coated photoresist composition is subject to a heat treatment (pre-bake) for about 30 to 60 seconds at 120° C. or less to form a photoresist layer. According to Japanese Patent Application Laid-Open No. 2006-309245, this process can reduce the movement or leaching of the acid and/or other photoresist materials from the photoresist layer into the immersion liquid.

### BRIEF DESCRIPTION OF THE DRAWINGS

FIGS. 1A and 1B are views illustrating a method of forming an organic thin film according to a first embodiment;

FIGS. 2A to 2D are views illustrating a distribution of molecules in coated organic solution;

FIGS. 3A and 3B are views illustrating a method of forming an organic thin film according to a second embodiment;

FIGS. 4A to 4D are views illustrating a distribution of molecules in coated organic solution;

FIGS. 5A and 5B are views illustrating a method of forming an organic thin film according to a comparative example; and

FIGS. 6A to 6C are views illustrating a distribution of molecules in coated organic solution.

### DETAILED DESCRIPTION

In general, according to one embodiment, a method of forming an organic thin film comprises coating organic solution onto a substrate and heating the coated organic solution after the coating. The organic solution contains a first component and a second component. The second component has higher hydrophobicity than hydrophobicity of the first component. The coating includes making the organic solution to be dropped onto the substrate, equalizing a thickness of the dropped organic solution in an atmosphere containing a vapor at a first vapor pressure, and equalizing the thickness of the dropped organic solution in an atmosphere containing the vapor at a second vapor pressure after the equalization in the atmosphere containing the vapor at the first vapor pressure. The vapor is formed by a vaporization of a liquid. The second vapor pressure is higher than the first vapor pressure.

Exemplary embodiments of a method of forming an organic thin film and an exposure method will be explained below in detail with reference to the accompanying drawings. The present invention is not limited to the following embodiments.

### First Embodiment

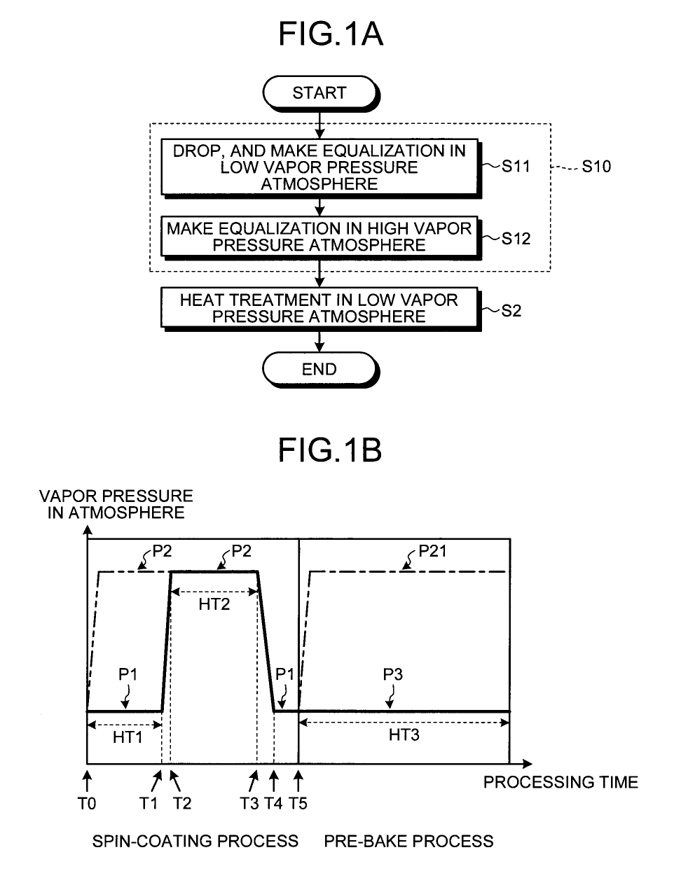

A method of forming an organic thin film according to a first embodiment will be described with reference to FIGS. 1A and 1B. FIG. 1A is a flowchart illustrating a method of forming an organic thin film according to the first embodiment. FIG. 1B is a view illustrating a vapor pressure in the method of forming an organic thin film according to the first embodiment.

In step S10, a conveyance system conveys a substrate to a coating apparatus. The coating apparatus coats (e.g. spin-coats) organic solution on the substrate by a spin coating method. The substrate is made of, for example, a semiconductor such as silicon. The organic solution contains a first component and a second component having higher hydrophobicity than that of the first component.

The first component may be a resin having photosensitivity. The first component is, for example, a positive chemically-amplified resist, which contains a base resin including a polar group of an alkali-soluble resin that is protected by a dissolution-inhibiting group (that is unstable to acid), and a photoacid generator. The base resin is an acrylic resin containing a photoacid-labile ester or acetal group, for example. The photoacid generator is, for example, a triphenylsulfonium group.

Alternatively, the first component is, for example, a negative chemically-amplified resist, which contains a base resin, a cross-linking agent that forms a cross-link by a condensation reaction with the base resin with an acid, and a photoacid generator. The base resin is, for example, an acrylic resin. The cross-linking agent is, for example, a urea resin. The photoacid generator is, for example, a triphenylsulfonium group.

Alternatively, the first component is, for example, a positive resist containing a novolac resin and a photosensitive agent. Alternatively, the first component may be a negative resist containing a cyclized isoprene and an azide compound.

The second component is, for example, a resin having higher hydrophobicity than that of the first component. The second component is, for example, a resin containing a fluorinated substituent (the one in which a hydrogen atom is substituted by a fluorine atom). The resin containing the fluorinated substituent is a resin formed by polymerizing tetrafluoroethylene, fluorinated aromatic group, or fluoro-styrene compound. In the resin described above, the fluorine atom may be substituted in a main chain of the resin, or in a side chain thereof.

Alternatively, the second component is, for example, a resin containing Si substituent (the one in which a hydrogen atom is substituted by a Si atom). The resin containing the Si substituent is, for example, a resin formed by polymerizing trialkylsilyl group. In the resin described above, the Si atom may be substituted in a main chain of the resin, or in a side chain thereof.

The step S10 includes a step S11 and a step S12. In the description below, the atmosphere in a substrate processing unit of the coating apparatus is maintained to be substantially the same temperature.

In the step S11, the coating apparatus makes the organic solution to be dropped onto the substrate, and equalizes the thickness of the dropped organic solution onto the substrate in an atmosphere (low vapor pressure atmosphere, low relative humidity) containing a vapor, which is formed by a vaporization of a liquid, at a vapor pressure (first vapor pressure) P1. The liquid that should be vaporized as the vapor can be the one having high hydrophilicity, i.e., the one into which the first component is slightly soluble (the first component is hardly-soluble with respect to the liquid). The liquid described above has, for example, water or alcohol as a main component. The vapor pressure P1 is, for example, 30 to 50% of a saturated vapor pressure.

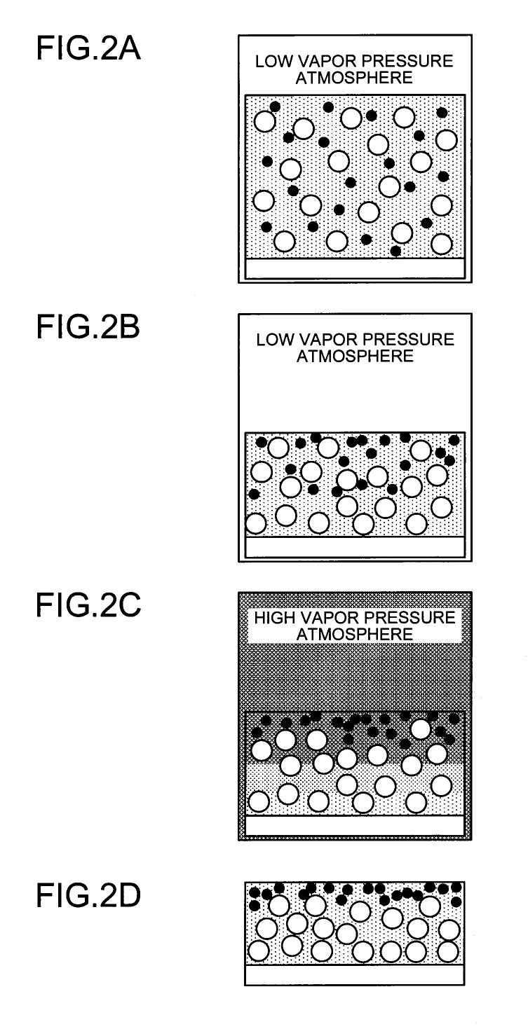

Specifically, at a timing T0 in FIG. 1B, the organic solution is dropped onto the substrate. In the organic solution immediately after dropped, the first component and the second component are mixed as a whole as illustrated in FIG. 2A. In FIG. 2A, the first component is indicated by a large white circle, while the second component is indicated by a small black circle.

Thereafter, the coating apparatus holds the vapor pressure in the atmosphere within the substrate processing unit at the vapor pressure P1 for a predetermined time HT1 as illustrated in FIG. 1B. The predetermined time HT1 is a time sufficient for drying the organic solution coated onto the substrate.

At a timing T1 when the predetermined time HT1 has elapsed from the timing T0, the first components and the second components are mixed in the vicinity of the surface in the dropped organic solution as illustrated in FIG. 2B.

In the step S12, the coating apparatus makes the thickness of the organic solution, which is dropped onto the substrate, equalize in an atmosphere (high vapor pressure atmosphere, high relative humidity) containing the vapor, which is formed by the vaporization of the liquid, at a vapor pressure (second vapor pressure) P2 that is higher than the vapor pressure P1. The vapor pressure P2 has a magnitude sufficient for allowing the vapor formed by the vaporization of the liquid to penetrate into the vicinity of the surface of the organic solution coated onto the substrate. The vapor pressure P2 is, for example, 70 to 90% of a saturated vapor pressure.

Specifically, the coating apparatus raises the vapor pressure in the atmosphere within the substrate processing unit to the vapor pressure P2 from the vapor pressure P1 during the period from the timings T1 to T2 illustrated in FIG. 1B.

Then, the coating apparatus holds the vapor pressure in the atmosphere within the substrate processing unit at the vapor pressure P2 for a predetermined time HT2 as illustrated in FIG. 1B. The predetermined time HT2 is a time sufficient for allowing the vapor formed by the vaporization of the liquid to penetrate into the vicinity of the surface of the organic solution coated onto the substrate.

At a timing T3 when the predetermined time HT2 has elapsed from the timing T2, the second components (small black circles) are eccentrically located in the vicinity of the surface of the organic solution, while the first components (large white circles) are eccentrically located from the inside to the bottom surface in the coated organic solution as illustrated in FIG. 2C.

Thereafter, the coating apparatus lowers the vapor pressure in the atmosphere within the substrate processing unit to the vapor pressure P1 from the vapor pressure P2 during the period from the timings T3 to T4 in FIG. 1B.

During the period from the timings T4 to T5, a conveyance system coveys the substrate having the organic solution coated thereon to a heat-treatment apparatus from the coating apparatus.

Next, in a step S2, the coated organic solution is subject to a heat treatment (pre-bake) in an atmosphere containing the vapor formed by the vaporization of the liquid at a vapor pressure (third vapor pressure) lower than the second vapor pressure P2. The vapor pressure P3 is, for example, 30 to 50% of the saturated vapor pressure. Thus, an organic thin film is formed (film-formation).

Specifically, the heat-treatment apparatus holds the vapor pressure in the atmosphere within the substrate processing unit at the vapor pressure P3 for a predetermined time HT3 from the timing T5 illustrated in FIG. 1B. The predetermined time HT3 is a time sufficient for allowing a surplus solvent medium contained in the organic solution, coated onto the substrate, to be evaporated so as to secure adherence between a material, which should be the organic thin film, and the substrate. When the first component contains a photosensitive component (photosensitive agent), the temperature in the heat treatment is controlled at the temperature that does not destroy the photosensitive component (photosensitive agent).

In this case, in the organic thin film, the second components are eccentrically located in the vicinity of the surface of the organic thin film, while the first components are eccentrically located from the inside to the bottom surface of the organic thin film as illustrated in FIG. 2D.

It should be noted that, when the organic thin film is employed for a photoresist, the conveyance system then conveys the substrate having the organic thin film formed thereon to an exposure apparatus from the heat treatment apparatus. The exposure apparatus performs a liquid immersion exposure process for transferring a predetermined pattern onto the organic thin film through a mask. In this case, in order to enhance the depth of focus, the organic thin film is exposed by light in a state where immersion liquid (pure water) having high refractive index is filled between a projecting optical system (projecting lens) of the exposure apparatus and the organic thin film formed on the substrate. Thus, a latent image is formed on the organic thin film.

After the liquid immersion exposure process is completed, the conveyance system conveys the exposed organic thin film and substrate to a development apparatus from the exposure apparatus. The development apparatus develops the latent image formed on the organic thin film by means of alkali developer. Then, the conveyance system may convey the developed organic thin film and substrate to a second heat-treatment apparatus, wherein the developed organic thin film may be subject to a heat treatment (post-bake) in order to enhance etching resistance of the organic thin film.

Alternatively, when the first component is the positive or the negative chemically-amplified resist, the conveyance system may convey the exposed organic thin film and the substrate to a third heat-treatment apparatus from the exposure apparatus, after the liquid immersion exposure process is completed. The third heat-treatment apparatus performs a heat treatment (post exposure bake) to the organic thin film in order to accelerate the reaction between the acid generated by the photoacid generator and the base resin. Thereafter, the conveyance system conveys the organic thin film and substrate to the development apparatus from the third heat-treatment apparatus. The process afterward is similar to that described above.

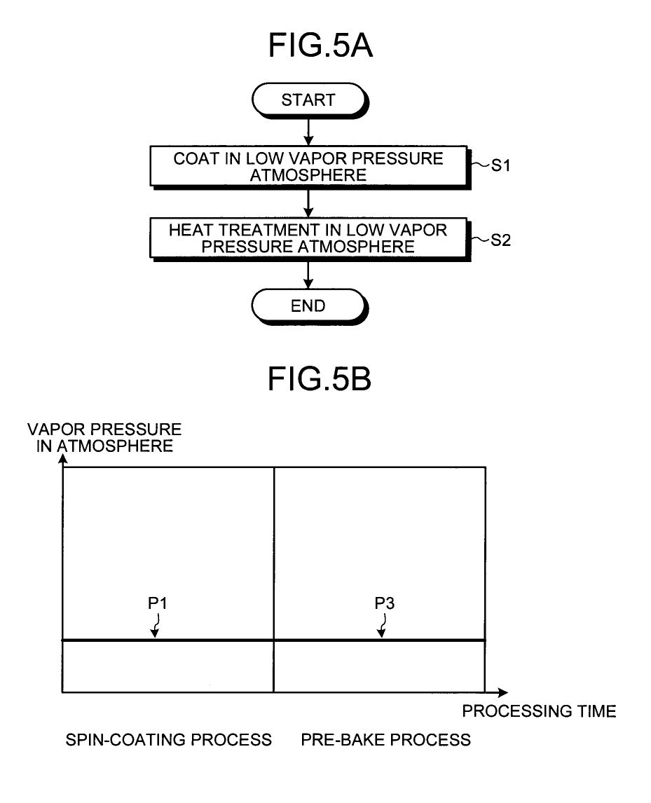

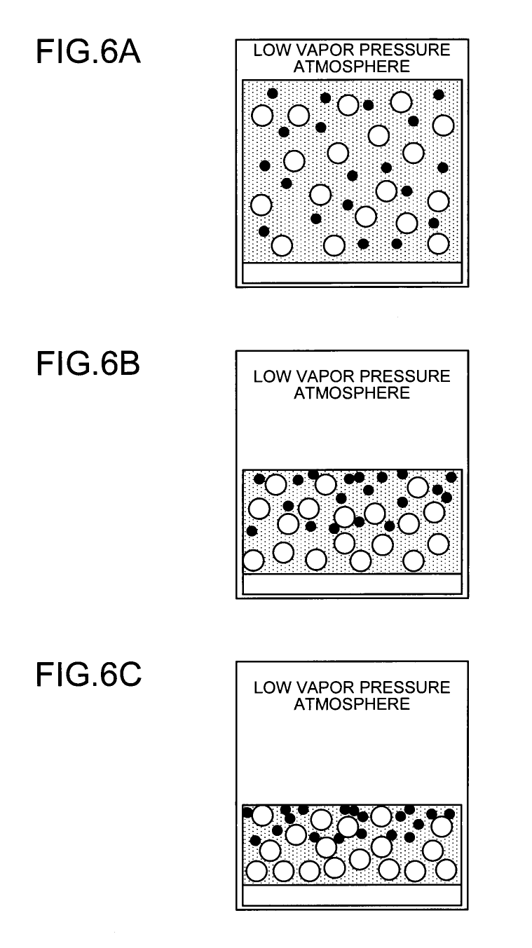

It is supposed here that the coating apparatus keeps on holding the vapor pressure in the atmosphere within the substrate processing unit at the vapor pressure P1, as illustrated in FIG. 5B, in the coating process (step S1) illustrated in FIG. 5A. In this case, the state in the coated organic solution is only changed from the state (see FIG. 6A) immediately after it is dropped in which the first components and the second components are mixed as a whole, to the state (see FIG. 6B) in which the first components and the second components are mixed in the region in the vicinity of the surface in the coated organic solution after the completion of the coating process. In the following heat treatment process (step S2), the heat-treatment apparatus performs the heat treatment to the organic solution having the state described above as illustrated in FIG. 5B. In this case, the heat-treatment apparatus continuously holds the vapor pressure in the atmosphere in the substrate processing unit at the vapor pressure P3. Thus, the formed organic thin film still has the mixture of the first components and the second components in the region in the vicinity of the surface as illustrated in FIG. 6C. Specifically, the molecular arrangement in the organic thin film is fixed in a state where the eccentric location of the second components having high hydrophobicity is insufficient, and the organic thin film with this state is formed as a film, whereby the film has a low surface contact angle.

On the other hand, according to the first embodiment, the thickness of the organic solution dropped onto the substrate is equalized in the atmosphere of the vapor pressure P1 in the coating process, and then, the thickness of the organic solution dropped onto the substrate is equalized in the atmosphere of the vapor pressure P2 higher than the vapor pressure P1. With the processes, the vapor formed by the vaporization of the liquid penetrates in the vicinity of the surface in the coated organic solution (dropped organic solution), whereby the first components and the second components, which are mixed in the vicinity of the surface of the organic solution, are easy to move. Then, the second components, which have affinity to the atmosphere (gas) having hydrophobicity regardless of the vapor pressure, basically move toward the surface, while the first components, which have low affinity to the atmosphere, basically move to the inside of the organic solution. Therefore, the organic thin film can be formed in which the second components are eccentrically located in the vicinity of the surface of the organic thin film, and the first components are eccentrically located from the inside to the bottom surface of the organic thin film. As a result, the second components are segregated to the surface of the organic thin film so as to be capable of efficiently enhancing hydrophobicity on the surface of the organic thin film, whereby the contact angle of the pure water on the surface of the organic thin film can be increased without increasing the contained amount of a component having high hydrophobicity.

According to the first embodiment, when the organic thin film is employed for a chemically-amplified photoresist, the contact angle of the immersion liquid (pure water) on the surface of the organic thin film can be increased in later liquid immersion exposure process, which can prevent the elution of the photoacid generator from the organic thin film into the pure water. Therefore, the reduction in the imaging precision (resolution) by the exposure apparatus can be prevented. Further, since the decrease in the amount of the photoacid generator contained in the organic thin film can be suppressed, the deterioration in the photosensitive precision (photosensitive performance) by the resist film can be suppressed. In addition, there is no need to increase the contained amount of the component having high hydrophobicity, so that the increase in the light scattering degree and the reduction in the solubility of the developing liquid, caused by the component having high hydrophobicity, can be prevented. From this point of view, the deterioration in the photosensitive precision (photosensitive performance) by the resist film can be suppressed. Accordingly, the defect formation of the resist pattern (generation of water spot) can be prevented.

Alternatively, it is supposed that the coating apparatus continuously holds the vapor pressure in the atmosphere within the substrate processing unit at the vapor pressure P2 in the coating process (in the step S11 and the step S12) as indicated by a two-dot-chain line in FIG. 1B. In this case, the coating apparatus keeps the state (see FIG. 2C) in which the vapor formed by the vaporization of the liquid penetrates in the vicinity of the surface of the coated organic solution before the organic solution coated on the substrate is dried. Therefore, the equalization of the thickness of the organic solution has to be carried out for a time, which is extremely longer than the total time (HT1+HT2) of the predetermined time HT1 and the predetermined time HT2, in order to dry the organic solution coated on the substrate. Specifically, it is difficult to efficiently (in a short period) perform a process of drying the organic solution coated onto the substrate, resulting in that the processing time in the coating process is increased (more than the time of HT1+HT2).

On the other hand, according to the first embodiment, the thickness of the organic solution dropped onto the substrate is equalized for the predetermined time HT1 in the atmosphere of the vapor pressure P1, and then, the thickness of the organic solution dropped onto the substrate is equalized for the predetermined time HT2 in the atmosphere of the vapor pressure P2 higher than the vapor pressure P1 in the coating process. Thus, if the coating apparatus performs the equalization of the thickness of the organic solution for the predetermined time HT1, the organic solution coated on the substrate can be dried. Specifically, the process of efficiently drying the organic solution coated on the substrate can be carried out (for a short period), whereby the increase in the processing time in the coating process (the increase more than the time HT1+HT2) can be prevented.

Alternatively, it is supposed that the heat-treatment apparatus performs the heat treatment (pre-bake) to the coated organic solution in the atmosphere (high vapor pressure atmosphere, high relative humidity) containing the vapor formed by the vaporization of the liquid at a vapor pressure P21, which is substantially equal to the vapor pressure P2, as indicated by a one-dot-chain line in FIG. 1B in the heat treatment process corresponding to the step S2. In this case, the state (see FIG. 2C) in which the vapor formed by the vaporization of the liquid penetrates in the vicinity of the organic solution is maintained, whereby the heat treatment has to be performed for a time that is extremely longer than the predetermined time HT3 in order to evaporate the surplus solvent component in the organic solution and to secure the adherence between the material that should become the organic thin film and the substrate. Specifically, it is difficult to efficiently perform the process of evaporating the surplus solvent component in the organic solution to secure the adherence between the material that should become the organic thin film and the substrate (for a short period).

On the other hand, according to the first embodiment, the coated organic solution is subject to the heat treatment (pre-bake) in the atmosphere of the vapor pressure P3 lower than the vapor pressure P2 in the heat treatment process (step S2). Accordingly, if the heat-treatment apparatus performs the heat treatment for the predetermined time HT3, the surplus solvent component in the organic solution can be evaporated, and the adherence between the material that should become the organic thin film and the substrate can be secured. Specifically, the process of evaporating the surplus solvent component in the organic solution to secure the adherence between the material that should become the organic thin film and the substrate can efficiently be performed (for a short period).

Alternatively, it is supposed that the liquid that should be vaporized as a vapor has low hydrophilicity, i.e., is the one into which the first component is easy to be soluble. The liquid described above contains, for example, an organic solvent (e.g., thinner) having low polarity as a major component. In this case, in the process in which the coating apparatus makes the thickness of the dropped organic solution equalize in the atmosphere of the vapor pressure P2 (high vapor pressure atmosphere, high relative humidity), there is a possibility that the vapor formed by the vaporization of the liquid penetrates not only in the vicinity of the surface of the coated organic solution but also into the deep portion of the inside of the organic solution. When the vapor penetrates into the deeper portion of the inside of the organic solution, the heat treatment has to be performed for a time that is extremely longer than the predetermined time HT3 in order to evaporate the surplus solvent component in the organic solution and to secure the adherence between the material that should be the organic thin film and the substrate in later heat treatment process (step S2). Specifically, it is difficult to efficiently perform the process of evaporating the surplus solvent component in the organic solution to secure the adherence between the material that should be the organic thin film and the substrate (for a short period).

On the other hand, according to the first embodiment, the liquid that should be vaporized as the vapor can be the one having high hydrophilicity, i.e., the one into which the first component is slightly soluble. The liquid described above contains, for example, water or alcohol as a major component. In this case, in the process (step S12) in which the coating apparatus makes the thickness of the dropped organic solution equalize in the atmosphere of the vapor pressure P2 (high vapor pressure atmosphere, high relative humidity), the vapor formed by the vaporization of the liquid can penetrate in the vicinity of the surface of the coated organic solution so as not to penetrate into the deeper portion at the inside of the coated organic solution. Thus, the process of evaporating the surplus solvent component in the organic solution to secure the adherence between the material that should become the organic thin film and the substrate can efficiently be performed (for a short period) in the following heat treatment process.

### Second Embodiment

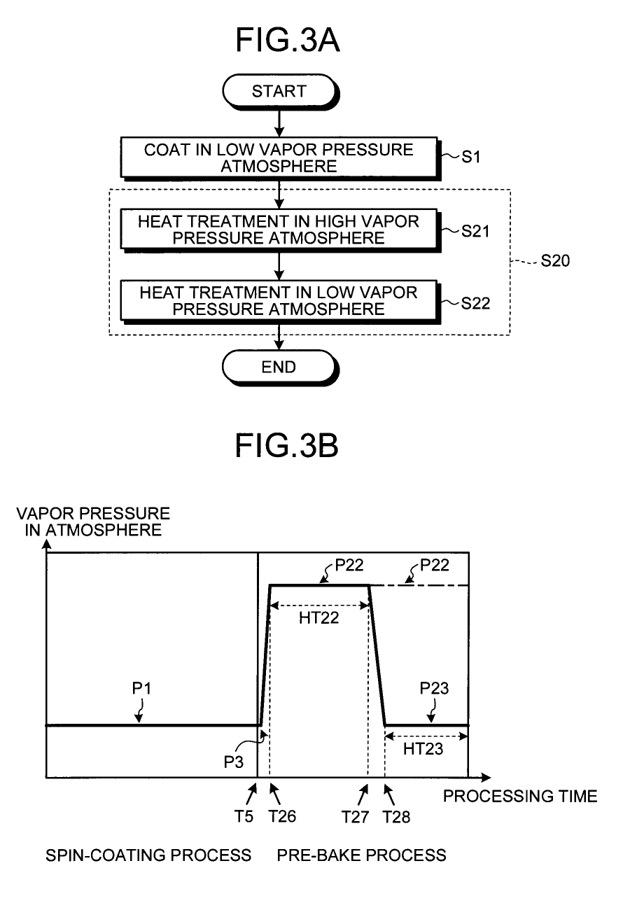

Next, a method of forming an organic thin film according to a second embodiment will be described with reference to FIGS. 3A and 3B. FIG. 3A is a flowchart illustrating the method of forming the organic thin film according to the second embodiment. FIG. 3B is a view illustrating the vapor pressure in the method of forming the organic thin film according to the second embodiment. In the following description, the points different from the first embodiment will mainly be described.

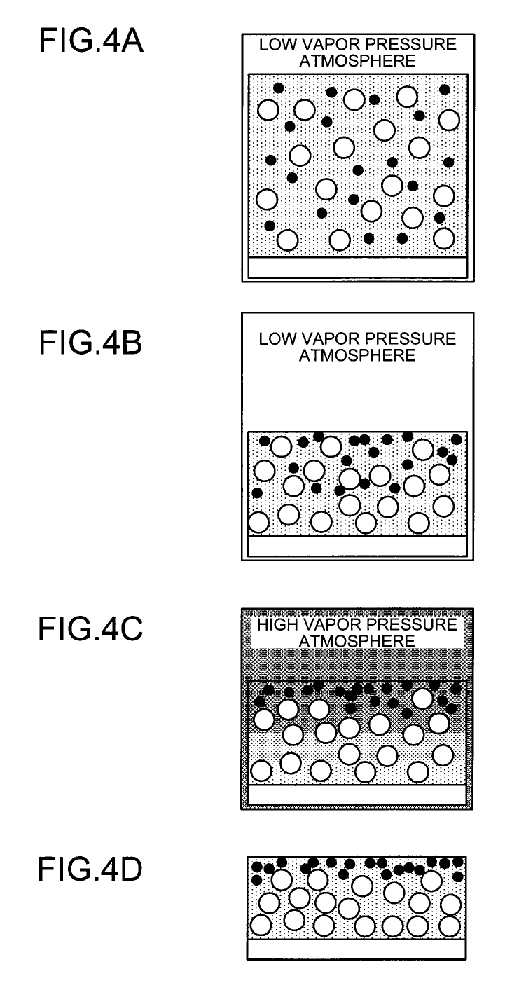

The method of forming the organic thin film according to the second embodiment includes a step S1 in which the vapor pressure in the atmosphere in the substrate processing unit is continuously maintained to be the vapor pressure P1, instead of the step S10 (see FIG. 1A). Thus, the state of the inside of the coated organic solution is changed from the state (see FIG. 4A) immediately after the organic solution is dropped in which the first components and the second components are mixed as a whole, to the state (see FIG. 4B) in which the first components and the second components are mixed in the region in the vicinity of the surface in the coated organic solution after the completion of the coating process.

Then, in a step S20 (heat treatment process), the coated organic solution is subject to a heat treatment (pre-bake). Thus, the organic thin film is formed (film formation). The step S20 includes a step S21 and a step S22.

In the step S21, the heat-treatment apparatus performs a heat treatment to the coated organic solution in the atmosphere (high vapor pressure atmosphere, high relative density) containing the vapor formed by the vaporization of the liquid at a vapor pressure (second vapor pressure) P22 higher than the vapor pressure P1. The vapor pressure P22 has a magnitude sufficient for allowing the vapor formed by the vaporization of the liquid to penetrate in the vicinity of the surface of the organic solution coated on the substrate. The vapor pressure P22 is, for example, 70 to 90% of the saturated vapor pressure.

Specifically, during a period from timings T5 to T26 in FIG. 3B, the heat-treatment apparatus raises the vapor pressure in the atmosphere within the substrate processing unit from the vapor pressure P3 (≈ vapor pressure P1) to the vapor pressure P22.

Thereafter, the heat-treatment apparatus holds the vapor pressure in the atmosphere within the substrate processing unit at the vapor pressure P22 for a predetermined time HT22. The predetermined time HT22 is the time sufficient for allowing the vapor formed by the vaporization of the liquid to penetrate into the vicinity of the surface of the organic solution coated onto the substrate.

It should be noted that, the heat-treatment apparatus may raise the vapor pressure in the atmosphere within the substrate processing unit at the vapor pressure P22 before the timing T5 illustrated in FIG. 3B. In this case, the conveyance system conveys the substrate having the organic solution coated thereon from the coating apparatus to the heat-treatment apparatus (in which the vapor pressure in the atmosphere in the substrate processing unit has already been the vapor pressure P22), thereby (e.g. immediately) starting the heat treatment to the coated organic solution. Thereafter, the heat-treatment apparatus holds the vapor pressure in the atmosphere within the substrate processing unit at the vapor pressure P22 for the predetermined time HT22, which is similar to described above.

At a timing T27 when the predetermined time HT22 has elapsed from the timing T26, in the coated organic solution, the second components (small black circles) are eccentrically located in the vicinity of the surface of the organic solution, while the first components (large white circles) are eccentrically located from the inside to the bottom surface of the coated organic solution as illustrated in FIG. 4C.

Thereafter, during the period from the timings T27 to T28 in FIG. 3B, the heat-treatment apparatus lowers the vapor pressure in the atmosphere within the substrate processing unit to a vapor pressure P23 from the vapor pressure P22. The vapor pressure (third vapor pressure) P23 is lower than the vapor pressure (second vapor pressure) P22. The vapor pressure P23 is 30 to 50% of the saturated vapor pressure, for example.

The heat-treatment apparatus holds the vapor pressure in the atmosphere within the substrate processing unit at the vapor pressure P23 for a predetermined time HT23 from the timing T28 in FIG. 3B. The predetermined time HT23 is a time sufficient for allowing a surplus solvent component in the organic solution, coated onto the substrate, to be evaporated so as to secure adherence between a material, which should become the organic thin film, and the substrate. When the first components contain a photosensitive component (photosensitive agent), the temperature in the heat treatment is controlled to be the temperature that does not destroy the photosensitive component (photosensitive agent).

In this case, in the organic thin film, the second components are eccentrically located in the vicinity of the organic thin film, while the first components are eccentrically located from the inside to the bottom surface of the organic thin film as illustrated in FIG. 4D.

According to the second embodiment, the coated organic solution is subject to the heat treatment in the atmosphere of the vapor pressure P22 higher than the vapor pressure P1 in the first half of the heat treatment process (step S21). With this process, the vapor formed by the vaporization of the liquid penetrates in the vicinity of the surface of the coated organic solution, whereby the first components and the second components, which are mixed in the vicinity of the surface of the organic solution, are easy to move. Then, the second components, which have affinity to the atmosphere (gas) having hydrophobicity regardless of the vapor pressure, basically move toward the surface, while the first components, which have low affinity to the atmosphere, basically move to the inside of the organic solution. Therefore, the organic thin film can be formed in which the second components are eccentrically located in the vicinity of the surface of the organic thin film, and the first components are eccentrically located from the inside to the bottom surface of the organic thin film. As a result, even by the second embodiment, the second components are segregated to the surface of the organic thin film so as to be capable of efficiently enhancing hydrophobicity on the surface of the organic thin film, whereby the contact angle of the pure water on the surface of the organic thin film can be increased without increasing the contained amount of a component having high hydrophobicity.

It is supposed that the heat-treatment apparatus holds the vapor formed by the vaporization of the liquid at the vapor pressure P22 in the latter half of the heat treatment process (the process corresponding to the step S22) as indicated by a one-dot-chain line in FIG. 3B. In this case, the state (see FIG. 4C) in which the vapor formed by the vaporization of the liquid penetrates in the vicinity of the organic solution is maintained, whereby the heat treatment has to be performed for a time that is extremely longer than the predetermined time HT23 in order to evaporate the surplus solvent component in the organic solution and to secure the adherence between the material that should become the organic thin film and the substrate. Specifically, it is difficult to efficiently perform the process of evaporating the surplus solvent component in the organic solution to secure the adherence between the material that should become the organic thin film and the substrate (for a short period).

On the other hand, according to the second embodiment, the coated organic solution is subject to the heat treatment (pre-bake) in the atmosphere of the vapor pressure P23 lower than the vapor pressure P22 in the latter half of the heat treatment process (step S22). Accordingly, if the heat-treatment apparatus performs the heat treatment for the predetermined time HT23, the surplus solvent component in the organic solution can be evaporated, and the adherence between the material that should become the organic thin film and the substrate can be secured. Specifically, the process of evaporating the surplus solvent component in the organic solution to secure the adherence between the material that should become the organic thin film and the substrate can efficiently be performed (for a short period).

It should be noted that the first embodiment and the second embodiment may be combined. Specifically, in the method of forming the organic thin film, the step S10 in FIG. 1A may be carried out, and then, the step S20 in FIG. 3A may be carried out.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of forming an organic thin film comprising:
coating organic solution onto a substrate, the organic solution containing a first component and a second component, the second component having higher hydrophobicity than hydrophobicity of the first component; and
heating the coated organic solution after the coating,
wherein the coating includes
making the organic solution to be dropped onto the substrate,
equalizing a thickness of the dropped organic solution in an atmosphere containing a vapor at a first vapor pressure, the vapor being formed by a vaporization of a liquid, and
equalizing the thickness of the dropped organic solution in an atmosphere containing the vapor at a second vapor pressure higher than the first vapor pressure, after the equalization in the atmosphere containing the vapor at the first vapor pressure.

2. The method of forming an organic thin film according to claim 1, wherein
the coating includes
holding the vapor pressure of the atmosphere at the first vapor pressure for a first time,
raising the vapor pressure of the atmosphere from the first vapor pressure to the second vapor pressure, and
holding the vapor pressure of the atmosphere at the second vapor pressure for a second time.

3. The method of forming an organic thin film according to claim 2, wherein
the first time is a time sufficient for drying the dropped organic solution, and
the second time is a time sufficient for allowing the vapor to penetrate in the vicinity of a surface of the dried organic solution.

4. The method of forming an organic thin film according to claim 1, wherein
the heating includes performing a heat treatment to the coated organic solution in an atmosphere containing the vapor at a third vapor pressure lower than the second vapor pressure.

5. The method of forming an organic thin film according to claim 4, wherein
the heating includes holding the vapor pressure of the atmosphere at the third vapor pressure for a third time, the third time being a time sufficient for evaporating a solvent component in the coated organic solution.

6. The method of forming an organic thin film according to claim 1, wherein
the heating includes performing a heat treatment to the coated organic solution at least in an atmosphere containing the vapor at a fourth vapor pressure higher than the first vapor pressure.

7. The method of forming an organic thin film according to claim 6, wherein
the heating further includes performing a heat treatment to the coated organic solution in an atmosphere containing the vapor at a fifth vapor pressure lower than the fourth vapor pressure, after the heat treatment in the atmosphere containing the vapor at the fourth vapor pressure.

8. The method of forming an organic thin film according to claim 1, wherein
the first component has a property of being slightly soluble for the liquid.

9. The method of forming an organic thin film according to claim 8, wherein
the liquid has water or alcohol as a major component.

10. A method of forming an organic thin film comprising:
coating organic solution onto a substrate, the organic solution containing a first component and a second component, the second component having higher hydrophobicity than hydrophobicity of the first component; and
heating the coated organic solution after the coating,
wherein the coating includes coating the organic solution in an atmosphere containing a vapor formed by a vaporization of a liquid, at a first vapor pressure, and
the heating includes performing a heat treatment to the coated organic solution at least in an atmosphere containing the vapor at a second vapor pressure higher than the first vapor pressure.

11. The method of forming an organic thin film according to claim 10, wherein
in the heating, the heat treatment to the coated organic solution is started after the vapor pressure of the atmosphere is set to be the second vapor pressure.

12. The method of forming an organic thin film according to claim 10, wherein
the heating further includes performing a heat treatment to the coated organic solution in an atmosphere containing the vapor at a third vapor pressure lower than the second vapor pressure, after the heat treatment in the atmosphere containing the vapor at the second vapor pressure.

13. The method of forming an organic thin film according to claim 12 wherein
the heating includes
holding the vapor pressure of the atmosphere at the second vapor pressure for a fourth time,
lowering the vapor pressure of the atmosphere from the second vapor pressure to the third vapor pressure, and
holding the vapor pressure of the atmosphere at the third vapor pressure for a fifth time.

14. The method of forming an organic thin film according to claim 13 wherein
the fourth time is a time sufficient for allowing the vapor to penetrate in the vicinity of a surface of the coated organic solution, and
the fifth time is a time sufficient for evaporating a solvent component in the coated organic solution.

15. The method of forming an organic thin film according to claim 10, wherein
the first component has a property of being slightly soluble for the liquid.

16. The method of forming an organic thin film according to claim 15, wherein
the liquid has water or alcohol as a major component.

17. An exposure method comprising:
forming an organic thin film onto the substrate, by coating organic solution onto a substrate in an atmosphere containing a vapor, the organic solution containing a first component and a second component, the first component including a photosensitive resin, the second component having higher hydrophobicity than hydrophobicity of the first component, the vapor being formed by a vaporization of a liquid, and thereafter by making the coated organic solution to be subject to a heat treatment; and
performing a liquid immersion exposure process to the substrate having the organic thin film formed thereon,
wherein the forming the organic thin film includes
making the organic solution to be dropped onto the substrate,
holding the dropped organic solution in the atmosphere containing the vapor at a first vapor pressure, and thereafter
setting the vapor pressure of the atmosphere to be a second vapor pressure higher than the first vapor pressure.

18. The exposure method according to claim 17, wherein
the coating includes
holding the vapor pressure of the atmosphere at the first vapor pressure for a first time,
raising the vapor pressure of the atmosphere from the first vapor pressure to the second vapor pressure, and
holding the vapor pressure of the atmosphere at the second vapor pressure for a second time.

19. The exposure method according to claim 17, wherein
in the coating, the vapor pressure of the atmosphere is set to be the first vapor pressure, and
in the heat treatment, the vapor pressure of the atmosphere is set to be the second vapor pressure.

20. The exposure method according to claim 17, wherein
the photosensitive resin contains a photoacid generator.
